(19) United States
(12) Patent Application Publication
(10) Pub. No.: US 2026/0309774 A1
(43) Pub. Date: Oct. 8, 2026

(54) SEMICONDUCTOR SWITCH WITH DEGRADATION DETECTION

(71) Applicant: Infineon Technologies AG, Neubiberg (DE)

(72) Inventor: Cristian Mihai Boianceanu, Bucharest (RO)

(21) Appl. No.: 19/460,071

(22) Filed: Jan. 26, 2026

(30) Foreign Application Priority Data
Feb. 18, 2025 (DE) 102025106113.0

(51) Int. Cl. G01R 31/28; G01R 19/165; H10D 84/80; H10D 89/60

(52) U.S. Cl. CPC G01R 31/2884; G01R 19/16519; H10D 84/817; H10D 89/711

(57) ABSTRACT

A semiconductor device with a power transistor is described. The power transistor has two or more gate electrodes to allow an individual switching of two or more respective groups of transistor cells. The semiconductor device includes a metallization layer, arranged on a semiconductor die, that forms a main electrode of the power transistor; a clamping circuit; a degradation detection circuit, which is configured to detect a degradation of the metallization layer, wherein the degradation detection circuit is integrated in the same semiconductor die as the first transistor; and a gate control circuit that is configured to activate and deactivate the two or more groups of transistor cells by providing gate signals to the two or more gate electrodes of the first transistor. When a degradation is detected by the degradation detection circuit and the clamping circuit is active, at least one group of transistor cells is inactive.

### TECHNICAL FIELD

The present disclosure relates to the field of power semiconductor switches, in particular to a semiconductor device with a power transistor and degradation detection capability.

### BACKGROUND

One concept for current measurement that is often used in connection with power transistors consists in the use of a so-called sense transistor. A power transistor (for example a DMOS transistor) is usually composed of a multiplicity of transistor cells connected in parallel (transistor cell array). However, some transistor cells of the cell array form a separate transistor, i.e. the sense transistor. The sense transistor can be operated approximately at the same operating point as the power transistor, but has a significantly smaller active area than the power transistor. The currents flowing through power transistor and sense transistor are thus approximately proportional in such an arrangement, wherein the proportionality factor K corresponding (at least theoretically) to the ratio of the active areas of the two transistors. That is, the active area of the sense transistor is smaller than the active area of the power transistor by the factor K.

During operation, the semiconductor chip, which includes the power transistor, may be exposed to a varying thermal load, which can lead—over time—to the degradation of the semiconductor chip and ultimately to the failure of the semiconductor chip. There are concepts for semiconductor chips which can carry out a so-called “health check” using integrated circuitry. However, these concepts are generally restricted to specific applications or they do not identify a specific problem until it is too late to ensure reliable continuation of operation (fail operational). With regard to the prior art, reference is made to the publication US 20230194595 A1.

### SUMMARY

A semiconductor device with a power transistor is described herein. In one embodiment, the power transistor is composed of a plurality of transistor cells, wherein the power transistor has two or more gate electrodes to allow an individual switching of two or more respective groups of transistor cells. The semiconductor device further includes a metallization layer, arranged on a semiconductor die, that forms a main electrode of the power transistor; a clamping circuit, which is configured to limit the voltage drop across the power transistor; a degradation detection circuit, which is configured to detect a degradation of the metallization layer, wherein the degradation detection circuit is integrated in the same semiconductor die as the first transistor; and a gate control circuit that is configured to activate and deactivate the two or more groups of transistor cells by providing gate signals to the two or more gate electrodes of the first transistor. When a degradation is detected by the degradation detection circuit and the clamping circuit is active, at least one group of transistor cells is inactive.

Furthermore, a method is described herein, which includes, in one embodiment, switching a power transistor on and off, wherein the power transistor is composed of a plurality of transistor cells and wherein the power transistor has two or more gate electrodes to allow an individual switching of two or more respective groups of transistor cells. The method further includes detecting a degradation of a metallization layer, arranged on a semiconductor die, that forms a main electrode of the power transistor; and limiting the voltage drop across the power transistor using a clamping circuit. When a degradation is detected and the clamping circuit is active, at least one group of transistor cells is prevented from becoming active.

### BRIEF DESCRIPTION OF THE DRAWINGS

The invention can be better understood with reference to the following drawings and descriptions. The components in the figures are not necessarily to scale; instead emphasis is placed upon illustrating the principles of the invention. Moreover, in the figures, like reference numerals designate corresponding parts. In the drawings:

FIG. 1 illustrates one example of a current measuring circuit which uses a sense transistor for current measurement;

FIG. 2 illustrates the example of FIG. 1 with additional illustration of the resistance of the chip metallization and with an additional clamping circuit;

FIG. 3 is an image, recorded by means of a microscope, of the surface of a semiconductor chip into which the circuit from FIG. 2 is integrated;

FIG. 4 is a schematic cross-sectional illustration through a semiconductor chip;

FIG. 5 is similar to the example of FIG. 2 with an additional degradation detection circuit.

FIG. 6 illustrates one example of a semiconductor device with a power transistor, wherein some transistor cells are not activated while a clamping circuit drives the power transistor into conductive (linear) state.

FIG. 7 is a flow chart illustrating the function of the circuit of FIG. 7.

### DETAILED DESCRIPTION

FIG. 1 shows one exemplary implementation of a current measuring circuit comprising a sense transistor. In the depicted example, an electrical load R_{LOAD} is switched by means of a power transistor T_{L}. The current flowing through the power transistor T_{L} (and hence also through the load R_{LOAD}) is designated by I_{LOAD}. The power transistor T_{L} may be a high-side switch as shown in FIG. 1. That is, the main current path of the power transistor T_{L} (drain-source current path in the case of a MOS transistor) is connected between a supply terminal VS and an output (output pin OUT), to which the load R_{LOAD} can be connected during operation. It is understood that the present disclosure is not limited to high-side transistors. The concepts described herein may readily be applied to circuits with low-side switches.

A current sense circuit 20, which includes a sense transistor T_{S}, is coupled to the power transistor T_{L}. The current sense circuit 20 is configured to provide a measurement current I₀ that represents the load current I_{LOAD} passing through the power transistor T_{L}. As mentioned in the introduction, the sense current I₀ is approximately proportional to the load current I_{LOAD}, i.e. I₀=I_{LOAD}/K (proportionality factor K). For a current measurement, the transistors T_{S} and T_{L} should have the same (or at least similar) characteristics and be operated (approximately) at the same operating point. Therefore, the gate electrodes of the two transistors T_{L} and T_{S} are connected to one another. Likewise, the drain electrodes of the two transistors T_{L} and T_{S} are connected to one another. Furthermore, in a high-side arrangement, the drain electrodes of the transistors T_{L} and T_{S} are connected to the supply terminal VS, at which a supply voltage V_{S} is applied during operation.

In order for both transistors T_{L} and T_{S} to operate at the same operating point, the drain-source voltages at both transistors T_{L} and T_{S} should be identical. In the depicted embodiment, this is achieved with the aid of the operational amplifier OA and the further transistor T₀ which together ensure that the source voltage at the sense transistor T_{S} is regulated to the same value as the source voltage at the power transistor T_{L}. As a consequence, the drain-source-voltages of both transistors, T_{L} an T_{S}, are essentially equal. It is noted that an operational amplifier is not necessarily required. Other concepts exist for ensuring the (approximate) proportionality between measurement current I₀ and load current I_{LOAD}. The specific implementation will depend on the requirements of the application.

In the example of FIG. 1, the sense transistor T_{S} and the further transistor T₀ (i.e. their main current paths) are connected in series, so that the same measurement current I₀ flows through both transistors, T_{S} and T₀. In the depicted example, the transistor T₀ is a p-channel MOS transistor, whereas the transistors T_{S} and T_{L} are n-channel MOS transistors. The gate of the transistor T₀ is driven by the output signal of the operational amplifier OA, wherein the inputs of the operational amplifier OA are coupled to the source electrodes of the transistors T_{S} and T_{L}. It is understood that a similar circuit can also be constructed with a p-channel transistor as power transistor (and sense transistor).

The operational amplifier OA and the transistor T₀ together implement a feedback loop. The inverting input of the operational amplifier OA is connected to the source electrode of the sense transistor T_{S}, and the noninverting input of the operational amplifier OA is connected to the source electrode of the power transistor T_{L}. If the source voltage at the sense transistor T_{S} is less than the source voltage at the power transistor T_{L}, then the voltage at the output of the operational amplifier O_{A} rises. As a result, the gate-source voltage at the transistor T₀ becomes smaller, which has the effect that the on-resistance of the transistor T₀ rises, which has the effect that the source voltage at the sense transistor T_{S} increases. Accordingly, feedback loop of the operational amplifier OA is stable and, consequently, the operational amplifier OA drives the transistor T₀ such that the voltages at the source electrodes of the transistors T_{L} and T_{S} are substantially equal, i.e. differences in the drain-source voltages of power transistor and sense transistor are compensated for. As a result, sense transistor and power transistor operate substantially at the same operating point.

In the example of FIG. 1, the sense current I₀ is output at a sense pin IS, and the output current at pin IS is denoted I_{S} (I_{S}=I₀ in the present example). A sense resistor R_{S} may be connected to the sense pin IS. The sense resistor R_{S} is usually connected between the sense pin IS and a reference voltage (e.g. ground potential, 0 V). The resulting voltage V_{IS} at the sense pin IS is then equal to the product of the current I_{S} and the resistance R_{S} (V_{IS}=R_{S}·IS=I_{LOAD}·RS/K). In other words, the resistor R_{S} converts the sense current I_{S} into a corresponding voltage signal.

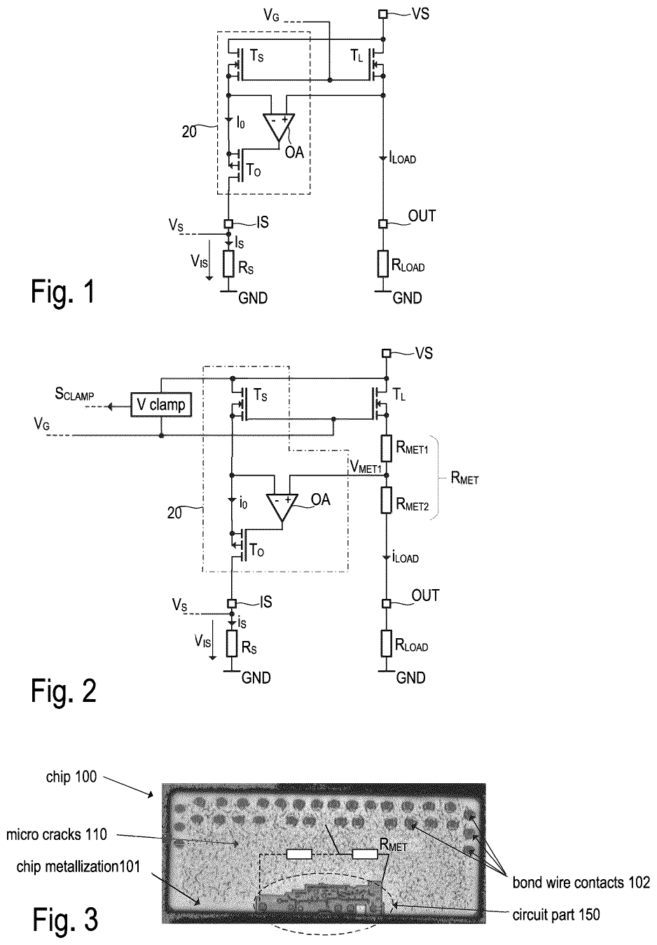

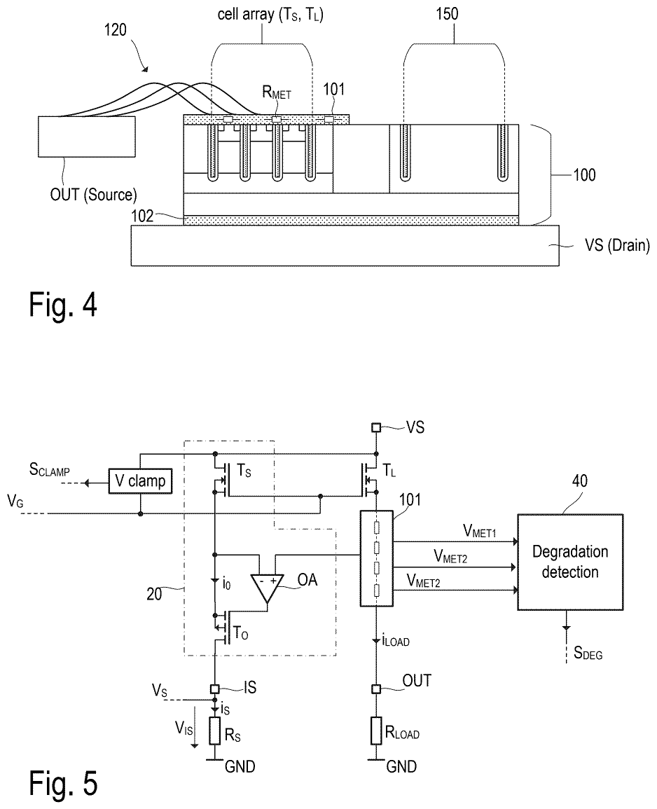

FIG. 2 illustrates essentially the same circuit as shown FIG. 1, wherein FIG. 2 includes an additional clamping circuit 21. Further, a resistances R_{MET1} and R_{MET2} (together R_{MET}) are shown, wherein the resistance R_{MET} is arranged between the source electrode of the power transistor T_{L} and the output pin OUT. The resistance R_{MET} is formed (inter alia) by the chip metallization and may thus be regarded as parasitic resistance. In the present example, the non-inverting input of the operational amplifier OA is connected to the chip metallization at a specific contact point, which can be regarded as the middle tap of a voltage divider composed into of the resistances, R_{MET1} and R_{MET2}. The resistances of interconnects (e.g. vias or plated-through holes connecting different metallization layers) also contribute to these resistances R_{MET1} and/or R_{MET2}. The resistance R_{MET} is a lateral resistance, i.e. the current through these resistance passes substantially in a lateral direction (i.e. substantially parallel to the chip surface), whereas the transistors T_{L} and T_{S} may be vertical transistors (see also FIG. 4), in which the current flows substantially “from top to bottom” through the transistor cell array in a direction that is substantially perpendicular to the chip surface.

The clamping circuit 21 is connected between drain and gate of the power transistor T_{L} and is configured to limit the voltage drop (drain-source voltage) across the power transistor T_{L} when switching off an inductive load. When the transistor T_{L} is switched off, without a clamping circuit, the drain-source voltage increases until the transistor breaks down. The clamping circuit (also referred to as active clamp) provides a protection mechanism against such a scenario. When the transistor T_{L} is on, it operates in saturation mode (on-resistance is low), but while switching the transistor off, it is driven into its linear mode, in which the on-resistance is higher. The inductive load demagnetizes quickly while the energy stored in the inductive load is dissipated in the clamping circuit. However, the junction temperature of the power transistor T_{L} may rise significantly while the clamping circuit is active because in operates in the linear mode. Amongst others, the temperature cycles caused by active clamping are one reason for degradation of the chip metallization.

FIG. 3 shows an enlarged image (photograph), taken by means of a microscope, of the semiconductor chip 100 which includes the circuit from FIG. 2. The image of the semiconductor chip 100 shows the chip metallization 101 which covers most of the chip surface. Furthermore, FIG. 3 illustrates contact locations 102 for bond wires connecting the chip metallization 101 to the output pin OUT of the chip 100. The output pin OUT itself cannot be seen in FIG. 3 because it is usually arranged on a leadframe on which the chip 100 is mounted.

Furthermore, FIG. 3 illustrates a circuit part 150 including the most of the circuitry required for driving and for operating the power transistor T_{L} as well as for the current measurement by means of the sense transistor. As mentioned, the power and sense transistors can be embodied as vertical transistors and be formed by a plurality of transistor cells of a cell array. In the case of vertical transistors, the drain-source current path runs from the top side of the semiconductor chip (visible in FIG. 3), through the chip to the bottom side of the chip. In the depicted example of FIG. 3, the chip metallization 101 forms the source electrode on the top side of the semiconductor die, whereas the drain electrode of the transistors T_{S} and T_{L} is situated on the bottom side of the semiconductor die.

A schematic illustration of the resistance R_{MET} is superimposed on the image of the semiconductor chip 100. At this point it is important to understand that the resistance R_{MET} is not a specific circuit component embodied (locally) at a specific location. Rather, the resistance runs in a lateral direction and is distributed over the entire chip metallization 101 (depending on what current density field forms in the metallization during operation).

The chip metallization 101 can be contacted (tapped) at a plurality of locations (e.g. at the node between R_{MET1} and R_{MET2}, see FIG. 2). In the example illustrated in FIG. 3, one contact of the resistance R_{MET} is situated in direct proximity to one of the chip contact locations 102 and a further contact is situated in the vicinity of the circuit part 150, in which for example the operational amplifier OA is also arranged. It is understood that the voltage divider R_{MET1}, R_{MET2} is a simplified model of the reality. The layer thickness of the chip metallization may be in the range of approximately 2-50 μm.

The chip contact locations 102 are for example those locations at which bond wires are connected to the chip metallization (e.g. by means of a wire bonding process). In other exemplary embodiments, clips, ribbons (ribbon bonding) or the like can also be used instead of bond wires. The geometry of the chip contact locations 102 can be different depending on the connection technique used.

The chip metallization 101 may be contacted at a plurality of locations. In the example illustrated in FIG. 3, a further contact is illustrated (on the left) in the vicinity of the circuit part 150. The resistance R_{MET} can then be regarded (in terms of modeling) as an electrical parallel connection of two (or more) resistances. The resistance value R_{MET} then represents an average value of different local current paths through the chip metallization 101.

As already mentioned, the semiconductor chip- and also the chip metallization 101—experiences a large number of temperature cycles during operation of the integrated circuit. As mentioned, the temperature cycles may be caused by the voltage clamping mechanism described above (clamping circuit 21). The (local) temperatures may fluctuate more or less regularly, between room temperature and, e.g. 300° Celsius or more. Cyclic temperature fluctuations of more than 200° Celsius are not unusual. These fluctuations may gradually result in microcracks 110 in the chip metallization 101, and the resistance value R_{MET} gradually increases due to the increasing number of microcracks. Investigations (by monitoring of the resistance value R_{MET}) have shown that for a specific change in the resistance value R_{MET} (e.g. a rise by 200%), a failure of the semiconductor chip became increasingly likely. Monitoring the resistance value R_{MET} therefore allows a prediction that the semiconductor chip is approaching its end of life before the chip actually fails. In the case of safety-critical applications such as e.g. in the case of certain components of autonomously driving vehicles, such a prediction may be a crucial advantage for avoiding greater damage.

Finally, it is noted that a change of the resistance R_{MET} also affects the proportionality factor K between sense current i₀ and load current i_{LOAD}. This is clear from FIG. 2. If the resistance R_{MET} changes due to defects such as micro cracks, delamination or the like, the voltage at the non-inverting input of the operational amplifier OA will also change. As a result, the operational amplifier OA cannot ensure equal source voltages at the transistors T_{S} and T_{L}.

FIG. 4 is a schematic cross-sectional view of the semiconductor chip of FIG. 3. It is understood that FIG. 4 is not true to scale and includes only those aspects necessary for understanding the exemplary embodiments discussed herein. The structure of such a semiconductor chip is as such known to a person skilled in the art.

A transistor cell array integrated in the semiconductor chip 100 is illustrated schematically on the left-hand side of FIG. 4. The depicted example includes vertical DMOS transistors T_{S} and T_{L}. The drain electrode is formed by the metallization 102 at the bottom side of the chip. The source electrode is formed by the metallization 101 at the top side of the chip 100. The bottom-side metallization may be mounted on a leadframe or any other chip carrier, e.g. by means of a die bonding process. The top-side metallization 101 is connected to the chip pin OUT of the leadframe, e.g. by means of a wire bonding process (bond wires 120). The resistance of the metallization 101 is symbolized by the resistance R_{MET} (cf. also FIG. 3). The circuit part 150 containing most of the other circuit components is situated on the right-hand side of FIG. 4. The resistance R_{MET} formed by the chip metallization 101 is formed in particular by that part of the metallization which is exposed to thermal loading during operation of the power transistor T_{L} and degrades due to this (cyclic) thermal loading.

Defects usually occurs close to those locations, at which the bond wires connect the metallization layer, wherein the thermal load causes (thermo-) mechanical stress and strain which again may lead to the mentioned defects such as cracks, delamination, etc. At this point, it is important to understand, that it is the temperature gradient (i.e. a temperature difference between two close points) which causes the mechanical stress and not the temperature as such.

The example of FIG. 5 is substantially the same as shown in FIG. 2. However, the circuit of FIG. 5 includes an additional degradation detection circuit 40, which is configured to detect a degradation of the metallization layer 101 (see FIG. 4) based on one or more voltages V_{MET1}, V_{MET2}, V_{MET3} tapped at the metallization layer. As mentioned, the metallization layer 101 may be regarded as a distributed resistance which can be tapped at various locations of the metallization layer 101. In FIG. 5, the metallization layer 101 is illustrated as a resistive voltage divider, which is also a simplified model of the reality. In fact, the metallization layer may be regarded as a complex resistive circuit composed of a plurality of transistors coupled in series and in parallel. The degradation detection circuit may be configured to amplify these voltages V_{MET1}, V_{MET2}, V_{MET3} and compare the amplified voltages with respective threshold values. A degradation of the metallization layer is detected if one or more of the amplified voltages V_{MET1}, V_{MET2}, V_{MET3} exceed the respective threshold values. The evaluation of voltages V_{MET1}, V_{MET2}, V_{MET3} tapped at different locations of the metallization layer may reveal information as to which specific portions of the metallization layer are affected. That is, the evaluation of voltages V_{MET1}, V_{MET2}, V_{MET3} may enable the degradation detection circuit to roughly localize the degraded parts of the metallization layer. In the depicted example, the signal S_{DEG} indicates whether, or not, a degradation has been detected. In some embodiments, the signal S_{DEG} indicates whether a degradation has been detected and, if so, which portion(s) of the metallization layer is (are) affected.

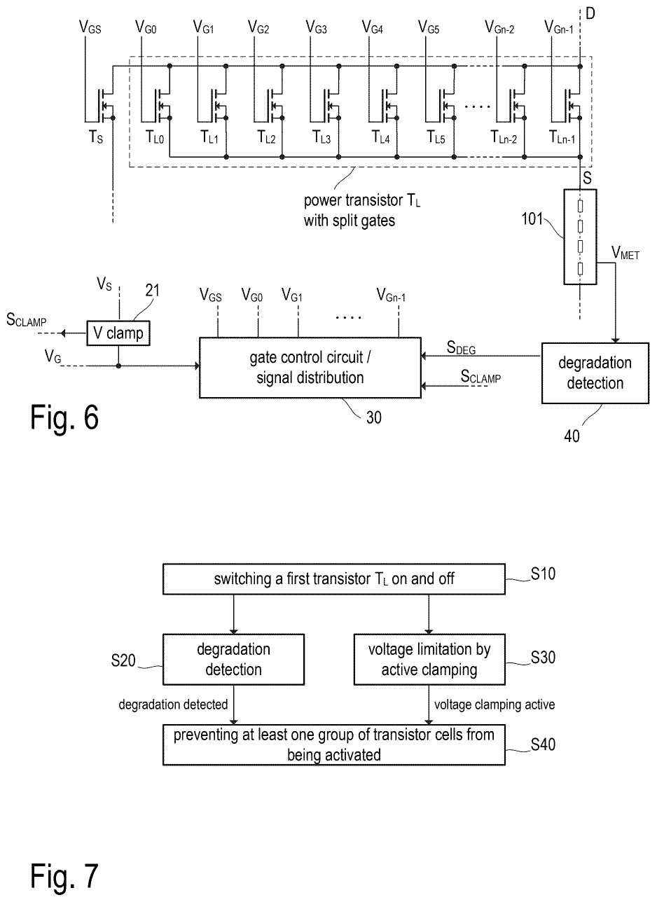

According to the embodiments described herein, a semiconductor device includes a power transistor T_{L} composed of a plurality of transistor cells, wherein the power transistor T_{L} has two or more gate electrodes to allow an individual switching of two or more respective groups of transistor cells T_{L0}, . . . T_{Ln-1}. A group of transistor cells may include one or more individual transistor cells. The power transistor is also referred to as split-gate transistor. An example is shown in FIG. 6 (upper part of the illustration).

A metallization layer 101 is arranged on a semiconductor die 100 that forms a first main electrode of the power transistor T_{L}. In case of an n-channel MOS transistor the first main electrode is the source electrode. The semiconductor device further includes a clamping circuit 21 configured to limit the voltage drop V_{DS} across the power transistor T_{L}, and a degradation detection circuit 40 configured to detect a degradation of a metallization layer based on one or more voltage signals V_{MET} tapped at the metallization layer 101 (see FIG. 4). In some embodiments, the degradation detection circuit 40 may be integrated in the same semiconductor die as the power transistor T_{L}.

The circuit illustrated in FIG. 6 also includes a gate control circuit 30 that is configured to individually activate and deactivate the mentioned groups of transistor cells T_{L0}, . . . T_{Ln-1} by providing respective gate signals V_{G0}, . . . V_{Gn-1} to gate electrodes of the power transistor T_{L}. When a degradation is detected by the degradation detection circuit 40 (and signaled by means of signal S_{DEG}) and the clamping circuit 21 is active (signaled by signal S_{CLAMP}), at least one group of the transistor cells is inactive (i.e. its activation is prevented). In this context a group of transistor cells being inactive means that the respective transistor cells are in a blocking state and no current can flow through them (apart from some negligible leakage current). In the example of FIG. 6, T_{L0} may represent a group of transistor cells which are not activated (i.e. are inactive) although the clamping circuit 21 is active and causes the other groups of transistor cells to operate in linear mode (thus allowing an inductive load to demagnetize).

The clamping circuit 21 becomes active when the voltage across the power transistor T_{L} becomes too high (i.e. higher than a threshold defined by the clamping circuit). In this case, the clamping circuit 21 pulls the gate voltage V_{G} up to a level that is high enough to prevent the transistor T_{L} from being switched off completely. However, when degradation is detected, the gate control circuit 30 will ensure that at least one group of transistor cells is off. By deactivating approximately 10 percent of the active area (transistor cells), temperatures around the bond wire contacts can be reduced, thus reducing local thermal stress and slow down the further degradation process.

As mentioned, the degradation detection circuit 40, may tap two or more voltage signals at the metallization layer 101 at two or more respective positions on the metallization layer 101. Each of the voltage signals (collectively denoted V_{MET}) may be processed and compared with a respective threshold to allow the degradation detection circuit 40 to roughly localize the degraded portions of the metallization layer 101. The degradation detection circuit 40 may signal, to the gate control circuit 30, which portions of the metallization layer 101 are degraded, and based on this information the gate control circuit 30 may decide which group(s) of transistor cells is (are) inactive when the clamping circuit 21 is active. The voltage signals V_{MET} may depend on the resistances of specific portions of the metallization layer 101. In essence, the degradation detection circuit 40 may detect an increased resistance of the metallization layer 101 or of certain portions of the metallization layer 101.

The concept described above is further illustrated by means of the flow chart of FIG. 7, which illustrates a method for operating a semiconductor device including a power transistor (see, e.g., transistor T_{L} of FIG. 6), wherein the power transistor is composed of a plurality of transistor cells and wherein the power transistor has two or more gate electrodes to allow an individual switching of two or more respective groups of transistor cells. According to FIG. 7, the method includes switching a power transistor on and off (box S10). The method further includes detecting a degradation of a metallization layer (box S20) which is arranged on a semiconductor die and which forms a main electrode (e.g. a source electrode) of the power transistor. The power transistor may be used to connect an inductive load with (and disconnect it from) a supply voltage. In order to protect the power transistor, the method includes limiting the voltage drop (e.g. drain source-voltage V_{DS}) across the power transistor using a clamping circuit (box S30). It is noted that various clamping circuits are as such known in the field of power electronics. Furthermore, the method includes when a degradation is detected and the clamping circuit is active-preventing at least one group of transistor cells from becoming active (box S40).

In one example, the clamping circuit may drive the power transistor so that it operates in linear mode allowing a demagnetization current to flow through the power transistor and to dissipate the energy stored in the inductive load). Some exemplary embodiments described herein are summarized below.

In one embodiment, the at least one group of transistor cells, which remains inactive while the clamping circuit is active, includes at least one transistor cell. In one embodiment, the gate control circuit is configured to select the at least one group of transistor cells (which remains inactive while the clamping circuit is active) based on an output of the degradation detection circuit. This output may indicate whether, or not, a degradation has been detected.

In some embodiments, it may indicate which portions of the metallization layer are degraded. Accordingly, the degradation detection circuit may be configured to detect a degradation of specific portions of the metallization layer by evaluating resistances of the specific portions of the metallization layer. Evaluating the resistances may be accomplished by evaluating voltage signals. Accordingly, in one embodiment, the degradation detection circuit may be configured to detect a degradation of specific portions of the metallization layer by evaluating voltage signals tapped at specific positions of the metallization layer, and evaluating the voltage signals may include comparing the voltage signals with respective thresholds. The voltage signals may be amplified before comparing the amplified signals with the respective thresholds.

In one embodiment, the at least one group of transistor cells (which remains inactive while the clamping circuit is active) depends on which specific portions of the metallization layer are detected as being degraded. Moreover, when the degradation detection circuit does not signal a degradation, the gate control circuit may activate at least a portion of the at least one group of transistor cells (which are inactive in the event of a detected degradation).

Although the invention has been illustrated and described with respect to one or more implementations, alterations and/or modifications may be made to the illustrated examples without departing from the spirit and scope of the appended claims. In particular regard to the various functions performed by the above described components or structures (units, assemblies, devices, circuits, systems, etc.), the terms (including a reference to a “means”) used to describe such components are intended to correspond—unless otherwise indicated—to any component or structure, which performs the specified function of the described component (e.g., that is functionally equivalent), even though not structurally equivalent to the disclosed structure, which performs the function in the herein illustrated exemplary implementations of the invention.

1. A semiconductor device comprising:
a first transistor comprising a plurality of transistor cells, wherein the first transistor includes two or more gate electrodes to allow an individual switching of two or more respective groups of transistor cells;
a metallization layer arranged on a semiconductor die, that forms a main electrode of the first transistor a clamping circuit which is configured to limit the voltage drop across the first transistor ;
a degradation detection circuit which is configured to detect a degradation of a metallization layer and
a gate control circuit that is configured to activate and deactivate the two or more groups of transistor cells by providing gate signals to the two or more gate electrodes of the first transistor wherein, when a degradation is detected by the degradation detection circuit and the clamping circuit is active, at least one group of transistor cells is inactive.

2. The semiconductor device of claim 1,
whereas the at least one group of transistor cells, which remains inactive while the clamping circuit is active, includes at least one transistor cell.

3. The semiconductor device of claim 1,
wherein the clamping circuit when active, is configured to drive the first transistor so that it operates in linear mode.

4. The semiconductor device of claim 1
wherein the gate control circuit is configured to select the at least one group of transistor cells, which remains inactive while the clamping circuit is active, based on an output of the degradation detection circuit

5. The semiconductor device of claim 1
wherein the degradation detection circuit is configured to detect a degradation of specific portions of the metallization layer by evaluating resistances of the specific portions of the metallization layer

6. The semiconductor device of claim 1
wherein the degradation detection circuit is configured to detect a degradation of one or more specific portions of the metallization layer by evaluating voltage signals tapped at the one or more specific positions of the metallization layer

7. The semiconductor device of claim 6,
wherein evaluating the voltage signals includes comparing the voltage signals with respective thresholds.

8. The semiconductor device of claim 7,
wherein evaluating the voltage signals includes amplifying the voltage signals and comparing the amplified voltage signals with respective thresholds.

9. The semiconductor device of claim 1,
wherein the at least one group of transistor cells, which remains inactive while the clamping circuit is active, depends on which specific portions of the metallization layer are detected as being degraded.

10. The semiconductor device of claim 1
wherein, when the degradation detection circuit does not detect a degradation, the gate control circuit is configured to activate at least a portion of the at least one group of transistor cells when switching on the first transistor

11. The semiconductor device of claim 1
the degradation detection circuit being integrated in the same semiconductor die as the first transistor

12. A method comprising:
switching a first transistor on and off, the first transistor comprising a plurality of transistor cells, wherein the first transistor includes two or more gate electrodes to allow an individual switching of two or more respective groups of transistor cells;
detecting a degradation of a metallization layer arranged on a semiconductor die, that forms a main electrode of the first transistor
limiting the voltage drop across the first transistor using a clamping circuit;
wherein, when a degradation is detected and the clamping circuit is active, at least one group of transistor cells is prevented from becoming active.

13. The method of claim 12,
wherein, when active, the clamping circuit drives the first transistor so that it operates in linear mode.

14. The method of claim 12,
wherein detecting a degradation of the metallization layer comprises detecting a degradation of one or more specific portions of the metallization layer by evaluating resistances of the one or more specific portions of the metallization layer (101).

15. The method of claim 14,
wherein the at least one group of transistor cells, which is prevented from becoming active while the clamping circuit is active, depends on which specific portion of the metallization layer is detected as being degraded.
